(19) United States
(12) Patent Application Publication
(10) Pub. No.: US 2009/0220773 A1
(43) Pub. Date: Sep. 3, 2009

(54) COATING OF A THERMALLY AND EROSIVELY STRESSED FUNCTIONAL COMPONENT

(76) Inventor: Manfred Laudenklos, Schoeneck (DE)

Correspondence Address: Muncy, Geissler, Olds & Lowe, PLLC, P.O. BOX 1364, FAIRFAX, VA, 22038-1364, US

(21) Appl. No.: 12/281,912

(22) PCT Filed: Feb. 15, 2007
(86) PCT No.: PCT/EP2007/001301

§ 371 Date: Jan. 28, 2009

(30) Foreign Application Priority Data
Mar. 7, 2006 (DE) 10 2006 010 875.2

(51) Int. Cl. B32B 5/16; C23C 14/28; B32B 15/04; C09D 1/00

(52) U.S. Cl. 428/329; 427/595; 428/457; 106/286.4; 428/331; 428/328

(57) ABSTRACT

The invention relates to a functional component from metal which is subject to a thermal load or a thermal load and erosion and to at least one surface of which a coating is applied, said coating consisting of a binder phase containing zirconium fluoride and a material embedded in said binder phase. The invention also relates to a mold release agent for producing said coating and to a method for applying said coating to a functional component.

The invention relates to a metallic functional component, which is exposed to thermal or thermal and erosive stress and to which on at least one surface a coating is applied, whereby the coating consists of a binder phase and material embedded in the binder phase. In addition, the invention relates to a separating agent for preparing a coating on a functional component and in addition to a method for producing a coating on a metallic surface of a functional component.

Components that are exposed to thermal or thermal and erosive stress and through which a medium flows or which are impinged by or exposed to a medium, fulfill, for example, the task of power transmission or a conductive surface. In this function, they are exposed to flowing or expanding media. In many cases, considerable temperature variations occur thereby, so that the components must meet the condition of temperature resistance. In many cases, deposits also occur in components in contact with flowing media, so that these components are generally provided with coatings. Typical examples of functional components of this type are, for example, pistons, cylinder heads, and the entire area of the exhaust gas recirculation system in a motor vehicle. Apart from the erosive stress on these components, these components are also subjected to high thermal stress and temperature variations. Highly different coatings and coating methods are known for protecting functional components of this type.

Unexamined German Patent Application No. DE 101 24 434 A1 discloses a method for producing a coating and a coating for metals or metal alloys such as steel, sintered metals, or aluminum alloys from the sectors of automotive and mechanical engineering. The purpose of this coating is to protect said materials from wear and corrosion. The coating in this case consists of an inorganic matrix phase, which consists at least largely of a phosphate and a material embedded therein. In an embodiment, the coating consists of an inorganic matrix phase of aluminum phosphate, in which materials, such as, for example, aluminum oxide or graphite, are embedded. Coatings of this type are preferably applied over water-based gels or dispersions of dissolved monoaluminum phosphate and powdered functional materials dispersed therein onto the substrate to be coated, dried, and baked in an oven at typical temperatures of 150° C. to 500° C.

Another coating for aluminum materials is known from German Patent Publication No. DE 699 08 837 T2. The coating here relates to the surface of a piston skirt, which has a hard anodized coating and a composite polymer coating applied to the hard anodized coating. The composite polymer coating comprises a plurality of solid and lubricating particles in a heat-resistant polymer matrix, which can withstand engine operating temperatures. The known lubricants materials—graphite, boron nitrite, molybdenum, etc.—are used in this case as lubricants.

The object of the present invention is to develop a coating of thermally or thermally and erosively stressed functional surfaces on components, which involves chemical bonding to the base material of the functional component and therefore opposes the erosive and thermal stresses of the functional components. In addition, the coating should be easy to apply and exhibit high adhesion to the base material. Moreover, the object of the invention is to provide a separating agent for preparing a layer of this type, which is economical to produce and easy to apply. Another object of the invention is to provide a method which is capable of producing such a layer and which produces high adhesion between the binder and the base material.

The object of the invention is attained in regard to the functional component provided with a coating to the effect that the binder phase is bound chemically to the base material of the functional component and that the binder phase is formed of a polymer of polymerized zirconium fluoride, whereby the functional component is part of an internal combustion engine. The use according to the invention of a binder phase of polymerized zirconium fluoride now makes it possible to produce chemical bonding with the base material, and therefore to create an adherent layer on the functional component. Such coatings increase the lifetime of the functional components and, with improved action, reduce the laborious and cost-intensive use of methods to improve thermal shock behavior of the base materials. Furthermore, deposits are avoided by means of the layer of the invention; this in turn serves to reduce motor vehicle emissions. In advantageous embodiment variants of the invention, structural parts in the form of Al₂O₃ and/or SiO₂ and/or TiO₂ and/or ZrO₂ are bound in the binder phase. In this case, the polymer chains surround the structural parts and bind the structural parts to the base material. In this case, the fluoride combines chemically with iron present in the base material or a nonmetal such as, for example, aluminum. An adherent layer is thereby produced on the functional component, which provides great certainty against erosive stresses by means of chemical bonding with the base material and the inclusion of the structural elements in the polymer chains. In this case, the hard structural parts, present as oxides, are used as a “wear substrate” and the binder phase as binders between the base material and structural element. The structural parts are present in a fraction of 80 nm to 200 nm and with up to 10% by weight form the largest amount of particle-like materials in the coating. The structural parts have a relatively coarse surface structure, so that, in one respect, the structural parts interlock with one another and simultaneously assure a good hold in the binder phase.

Preferably, primary parts in the form of Al₂O₃ and/or SiO₂ and/or ZnO and/or TiO₂ and/or ZrO₂ and/or CeO are introduced into the binder phase with the structural parts. The primary parts are inserted in the gaps between the structural parts. In particular, because of the size of the primary parts of 2 nm to 80 nm, the primary parts are optimally suited to function as fillers between the structural parts. A very smooth surface results, which in turn counteracts erosion and deposition of soot particles impacting the functional part and present in, for example, an exhaust gas of an exhaust gas recirculation channel. The very smooth and resistant surface therefore facilitates the advantage of the invention that the functional components provided with a coating of the invention have a long lifetime. The primary parts are preferably present in the coating in amounts of 1% by weight to 3% by weight.

In another advantageous embodiment variant of the invention, sliding parts in the form of boron nitrite and/or magnesium aluminum silicate and/or molybdenum disulfide and/or silicate minerals, for example, mica, are integrated into the binder phase. The sliding parts are present in the coating in amounts of up to 5% by weight. The much larger sliding parts with expansions of 2 μm to 15 μm are also held by the polymer chains or lie between the structural parts in the coating.

Thicknesses between 1 μm and 80 μm are provided preferably as layer thicknesses. Preferably, a thickness between 25 μm and 60 μm is present on the surface of the functional component. Functional components are, for example, components such as pistons, a cylinder head, or parts of the exhaust gas recirculation system in a motor vehicle. In this case, the functional components are made of aluminum alloys or steel. It is also possible to form a coating of the invention on a functional component made of cast iron, particularly cast iron in the form of GG, GGG, and GGV.

The object of the invention is attained in regard to the separating agent for preparing a coating on a functional component to the effect that the separating agent is formed of deionized water and contains the following components:
an acidifier, particularly in the form of sodium hydroxide solution and/or potassium hydroxide solution and/or aluminum chloride,
a binder of zirconium fluoride, particularly in the form of H₂ZrF₆, and
an organic dispersant, such as, for example, mica.

It is possible by means of the acidifier to adjust the acid content and thereby the pH of the separating agent and thereby to control the polymer reaction rate and formation. Preferably, a pH of 4 to 5 is established in the separating agent. It is now possible with the use of the separating agent to produce a coating according to claim 1. In a preferred embodiment, structural parts and primary parts are present in the separating agent, said parts which are applied to the surface of the material of the functional component by spraying or dipping of the functional component. It is also advantageous to introduce sliding parts in the form of boron nitrite and/or magnesium aluminum silicate and/or molybdenum disulfide into the separating agent. The fractions of the structural parts in this case range from 80 nm to 200 nm, that of the primary parts from 2 nm and 80 nm, and that of the sliding parts from 2 μm and 15 μm. Gelatin which forms nanoparticles independently is advantageous in this case. In the limits cited in the dependent claims, binders in an amount of up to 5% by weight are added to the separating agent. The structural parts are added to the separating agent with up to 10% by weight, the primary parts up to 3% by weight, and the sliding parts in an amount of up to 5% by weight.

A separating agent that has a high liquidity and is sprayed on the surface of the functional component preferably by simple means can be prepared by the targeted selection of the addition of structural parts, primary parts, sliding parts, and zirconium fluoride as binder.

In regard to the method for producing the coating on a surface of the functional component, the coating of the invention is produced by first providing the surface with a separating agent and then heating the functional component to a temperature of at least 200° C., so that chemical bonding of the fluoride with the base material and polymerization of the binder occur. Advantageously, the heating is produced by means of a high-frequency electric field that is applied, for example, capacitively or inductively to the functional component. The surface can be heated very uniformly by this direct warming up, as occurs, for example, during inductive heating. Preferred frequency ranges for heating by means of a high-frequency electric field in this case are 100 kHz up to 10 MHz, about 4 MHz being used preferably. During heating at 4 MHz, a penetration depth of the fluoride of 0.2 to 0.3 mm therefore results. A very well adhering coating can be produced thereby on the functional component.

The polymer chains are used, on the one hand, to hold the layer together and, on the other, they are advantageous because they grow during thermal stress and therefore the elasticity of the layer increases. During cyclic thermal stress, therefore, no premature component failure occurs due to crack formation in the coating, because the coating of the invention can follow the expansion of the base material elastically. A temperature resistance up to about 1300° C. can be achieved by the layer structure of the invention. The employed fluoride binder systems have a polymerization temperature of about 220° C. and a vitrification point of 830° C. The adhesion to the base material is hereby also assured in the nearly vitrified or vitrified state by the chemical binding to the base material. Preferably, however, attention must be paid to the fact that the operating temperatures in the area of application of the functional components is below the vitrification point, so that the coatings are similar to that of the base material in the elastic range and therefore in their coefficient of expansion.

1. A metallic functional component, which is exposed to thermal or thermal and erosive stress and to which on at least one surface a coating of a binder phase and a material embedded in the binder phase is applied, wherein the functional component is part of an internal combustion engine and that the binder phase is bound chemically with the base material of the functional component and the binder phase is formed from a polymer of polymerized zirconium fluoride.

2. The functional component according to claim 1, wherein the material embedded in the binder phase is a structural part in the form of Al₂O₃ and/or SiO₂ and/or TiO₂ and/or ZrO₂ in a fraction of 80 nm to 200 nm, whereby the structural parts are surrounded by the polymer.

3. The functional component according to claim 2, wherein the material embedded in the binder phase is formed from primary parts in the form of Al₂O₃, SiO₂, ZnO, ZrO₂, CeO, and TiO₂ in a fraction of 2 nm to 80 nm, whereby the primary parts are inserted in the gaps between the structural parts and the primary parts are surrounded by the polymer.

4. The functional component according to claim 1, wherein the material embedded in the binder phase is a sliding part in the form of boron nitrite and/or magnesium aluminum silicate and/or molybdenum disulfide in a fraction of 2 μm to 15 μm, whereby the sliding parts are surrounded by the polymer.

5. The functional component according to claim 1, wherein the functional component is formed from an aluminum alloy or steel or cast iron, particularly cast iron in the form of GG, GGG, and GGV.

6. The functional component according to claim 5, wherein the functional component is an iron-containing component and that the coating is bound to the base material by means of bound iron fluoride.

7. The functional component according to claim 1, wherein the layer is present on the surface in a thickness of 1 μm to 80 μm, preferably in a thickness of 25 μm to 60 μm.

8. The functional component according to claim 1, wherein the functional component is a piston, a cylinder head, or part of an exhaust gas recirculation system.

9. A separating agent for preparing a coating on a functional component, wherein the separating agent is formed of deionized water and contains at least the following components:
an acidifier, particularly in the form of sodium hydroxide solution and/or potassium hydroxide solution and/or aluminum chloride, and
a binder of zirconium fluoride.

10. The separating agent according to claim 9, wherein an amount of structural parts in the form of Al₂O₃ and/or SiO₂ in a fraction of 80 nm to 200 nm is present in the separating agent.

11. The separating agent according to claim 10, wherein an amount of primary parts in the form of Al₂O₃ and/or SiO₂ and/or ZnO and/or TiO₂ and/or ZrO₂ and/ or CeO in a fraction of 2 nm to 80 nm is present in the separating agent.

12. The separating agent according to claim 9, wherein an amount of sliding parts in the form of boron nitrite and/or magnesium aluminum silicate and/or molybdenum disulfide in a fraction of 2 μm to 15 μm is present in the separating agent.

13. The separating agent according to claim 9, wherein a pH of 4 to 5 is established in the separating agent by means of the acidifier.

14. The separating agent according to claim 9, wherein the amount of the binder in the separating agent is less than or equal to 5% by weight.

15. The separating agent according to claim 9, wherein the amount of the structural parts in the separating agent is less than or equal to 10% by weight.

16. The separating agent according to claim 9, wherein the amount of primary parts in the separating agent is less than or equal to 3% by weight and is preferably between 1% by weight and 3% by weight.

17. The separating agent according to claim 9, wherein the amount of the sliding parts in the separating agent is less than or equal to 5% by weight.

18. A method for producing a coating on a metallic surface of a functional component, according to claim 1, by means of a separating agent, wherein
the surface is first provided with the separating agent and
wherein the functional component is heated to a temperature of at least 200° C., so that chemical bonding of the fluoride with the base material and polymerization of a binder in the separating agent occur.

19. The method according to claim 18, wherein the heating occurs inductively or capacitively by means of a high-frequency electric field in a frequency range of 100 kHz to 10 MHz, preferably in a frequency range of 4 MHz.
